(19) United States
(12) Patent Application Publication
(10) Pub. No.: US 2006/0282746 A1
(43) Pub. Date: Dec. 14, 2006

(54) METHOD AND APPARATUS FOR ACCESSING DATA STORED ON AN OPTICAL DISC

(76) Inventors: Hui-Huang Chang, Hsin-Chu Hsien (TW); Nai-Heng Tseng, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/383,755

(22) Filed: May 16, 2006

(30) Foreign Application Priority Data
May 17, 2005 (TW) 094115982

(51) Int. Cl. H03M 13/00

(52) U.S. Cl. 714/758

(57) ABSTRACT

The present invention provides an apparatus for accessing data stored on an optical disc. The apparatus includes a PI decoding module, a storage unit, and a PO decoding module. The PI decoding module is utilized for PI decoding and correcting the digital data read from the optical disc to generate a first digital data. The storage unit is utilized for storing the first digital data generated by the PI decoding module. The PO decoding module is utilized for PO decoding and correcting according to the first digital data generated by the PI decoding module to generate a second digital data and writing the second digital data to the storage unit. The first digital data is a portion of an ECC block.

### BACKGROUND OF THE INVENTION

1. Field of the Invention

The present invention relates to a method and apparatus for accessing data stored on an optical disc, especially to a method and apparatus for accessing data stored on a DVD.

2. Description of the Prior Art

Please refer to FIG. 1. FIG. 1 shows a block diagram of a prior art DVD data accessing system 100. A detailed description of the DVD data accessing system 100 is described as follows.

(a) An analog signal read from the disc 110 by the pick-up head 111 is converted into a digital EFM data 113 by an analog signal processor 112. After being demodulated by the EFMPLUS demodulator 114, the EFM data 313 becomes the row data 115 in a unit of bytes.

(b) The row data interface 116 stores the row data 115 to the memory 121 under the control of the memory controller 120.

(c) While the data stored into the memory 121 by the row data interface 116 can be assembled as an error correction code (ECC) block, the Reed Soloman Product Code (RSPC) decoder 117 accesses the data stored in the memory 121 via the memory controller 120 to decode PI data so as to correct the data stored in the memory 121.

(d) The RSPC decoder 117 accesses the data stored in the memory 121 via the memory controller 120 to decode PO data so as to correct the data stored in the memory 121.

(e) The error detection code (EDC) processor 118 accesses the data stored in the memory 121 via the memory controller 121. The error detection code (EDC) of each of the 16 data sectors in the ECC block is calculated.

(f) If all error detection codes (EDC) are correct, i.e., if data of an ECC block can be successfully decoded, the host 122 reads the ECC block from the memory 121 through a host interface 119 and the memory controller 120.

As mentioned above, before the data accessing system 100 completes the transmission of a entire ECC block, data of an amount equal to an ECC block are written into the memory 121 in step (b), and data of an amount equal to the ECC block are respectively read from the memory 121 in steps (c), (d), (e), and (f). Therefore, the prior art DVD data accessing system 100 accesses the memory 121 a great number of times and with a large amount of data operations while transmitting an ECC block, causing a requirement that the memory bandwidth be sufficiently large.

For the sake of lowering the bandwidth requirement of the memory, U.S. Pat. No. 6,662,335 disclosed an alternative DVD data accessing system 200. The block diagram of the DVD data accessing system 200 is shown in FIG. 2, and a detailed description of the DVD data accessing system 200 is described as follows.

(a) An analog signal read from the disc 210 by a pick-up head 211 is converted into a digital EFM data 213 by an analog signal processor 212. The EFM data 213 is demodulated by an EFMPLUS demodulator 214 and then becomes a row data 215 in a unit of bytes.

(b) The row data 215 is stored into a row buffer 218 via a row data interface and first inner-code decoder 216. When the data stored in the row buffer 218 can be assembled into a set of inner-code parity (PI), an inner-code parity decoding operation is performed on the set of data by the row data interface and first inner-code decoder 216. A set of inner-code data is obtained by this decoding step. When the set of inner-code data can be assembled as a sector, an error detection code (EDC) of the sector is then generated by the error detection code (EDC) generator 217. The sector and its corresponding error detection code are stored into the memory 221 via the memory controller 220.

(c) When the data stored in the memory 221 can be assembled as an ECC block, the RSPC decoder 225 reads the ECC block from the memory 221 via the memory controller 220, and performs an outer-code parity (PO) decoding operation on the ECC block. When an error occurs in the step of outer-code parity decoding, the data stored in the memory 221 is refreshed. Moreover, these error detection codes of the ECC block are stored into the error detection correction (EDC) file 223 by the error detection code (EDC) processor 224.

(d) The host interface 219 inspects whether the error detection codes in the error detection code file 223 are correct. If the error detection codes are correct, which means the decoding process is successful, the ECC block stored in the memory 221 is sent to the host 222 via the host interface 219.

As mentioned above, before the data accessing system 200 completes the transmission of an entire ECC block, data of an amount equal to that of an ECC block are written into the memory 221 in step (b), and data of an amount equal to that of the ECC block are respectively read from the memory 221 in steps (c), and (d). Therefore, during transmitting an ECC block, the amount of data accessed by the DVD data accessing system 200 is much less than the amount of data accessed by the prior art data accessing system 100. However, if the requirement for the memory bandwidth can be further reduced, the system efficiency will be further enhanced.

### SUMMARY OF THE INVENTION

It is therefore an objective of the claimed invention to provide a method and the corresponding apparatus for accessing data stored on an optical disc.

According to an embodiment of the claimed invention, an apparatus for accessing data on an optical disc is disclosed. The apparatus comprises an inner-code parity (PI) decoding module, a storage device, and an outer-code parity (PO) decoding module. The inner-code parity (PI) decoding module takes charge of PI decoding and correcting a piece of digital data read from the optical disc to generate a piece of first digital data. The storage device takes charge of storing the first digital data outputted from the PI decoding module. The outer-code parity (PO) decoding module takes charge of PO decoding and correcting the first digital data outputted from the PI decoding module to generate a piece of second digital data, and writing the second digital data to the storage device. The first digital data are a portion of an error correction code (ECC) block.

According to another embodiment of the claimed invention, a method for accessing data on an optical disc is disclosed. The method comprises: reading data from the optical disc to generate a piece of digital data; generating a piece of first digital data by PI decoding and correcting the digital data; storing the first digital data in a second line buffer and a storage device; and generating a piece of second digital data by PO decoding and correcting the first digital data outputted from the second line buffer and storing the second digital data in the storage device. The first digital data are a portion of an error correction code (ECC) block.

According to another embodiment of the claimed invention, a method for accessing data on an optical disc is disclosed. The method comprising: (a) reading data from the optical disc to generate a piece of digital data, wherein the digital data correspond to an error correction code (ECC) block; (b) PI decoding and correcting a portion of the digital data; (c) PO decoding and correcting the result generated in step (b) and storing the result of the PO decoding and correcting process in a storage device; and (d) repeating steps (b) and (c) until the entire digital data are PI and PO decoded and corrected.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows the block diagram of a prior art DVD data accessing system 100.

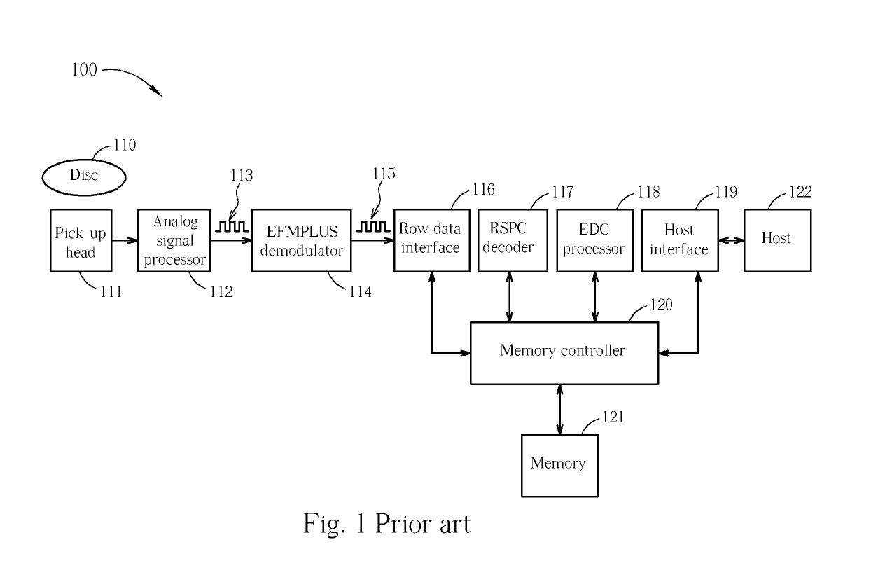

FIG. 2 shows the block diagram of a DVD data accessing system 200.

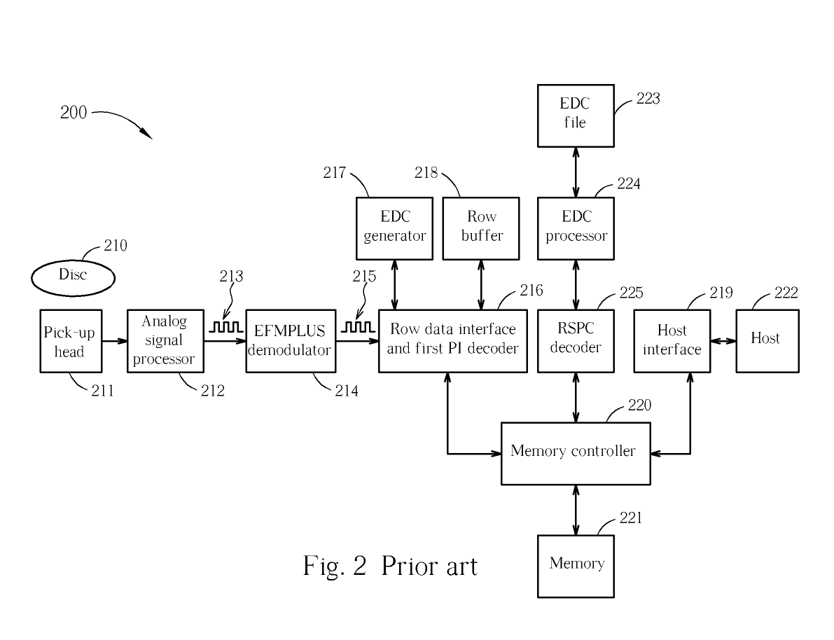

FIG. 3 shows a DVD data accessing system 300 according to a first embodiment of the present invention.

FIG. 4 shows a DVD data accessing system 400 according to a second embodiment of the present invention.

### DETAILED DESCRIPTION

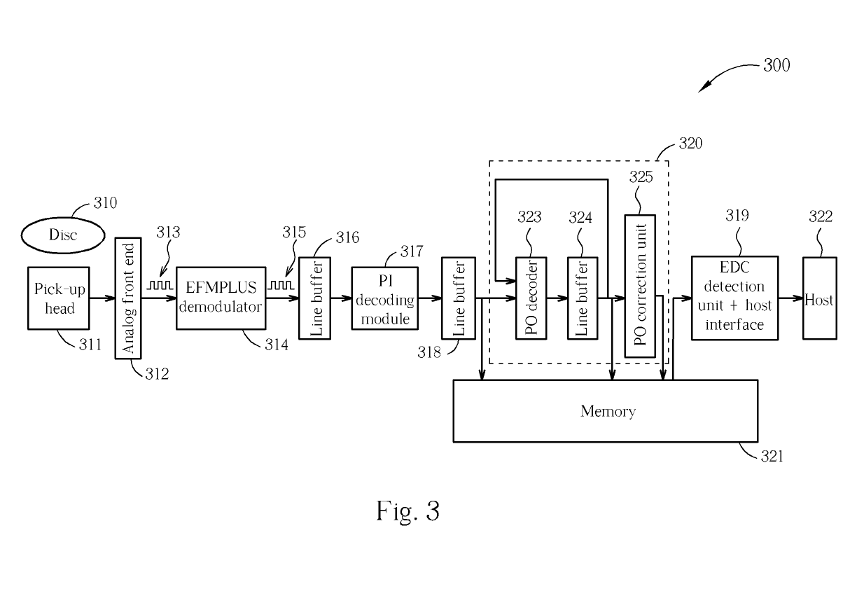

Please refer to FIG. 3. FIG. 3 shows a DVD data accessing system 300 according to a first embodiment of the present invention. In the first embodiment, data are transmitted in the unit of an ECC block. An ECC block contains a plurality of sectors of data together with inner-code parity (PI) and outer-code parity (PO). Because the data transmission unit of a DVD is well known by those skilled in the art, a detailed description is omitted here for the sake of brevity. The operation of the data accessing system 300 is described as follows.

(a) An analog signal read from the disc 310 by a pick-up head 311 is converted into a digital EFM data 313 by an analog front end 312. The EFM data 313 is demodulated by an EFMPLUS demodulator 314 and then turns into a row data 315, which is a part of an ECC block.

(b) The row data 315 is temporarily stored in the line buffer 316. When the row data stored in the line buffer 316 is large enough to perform inner-code parity decoding and correction, these data are transmitted to a PI decoding module 317 to perform inner-code parity decoding and correction. The data that have been processed by inner-code decoding and correction become first digital data and are stored in a line buffer 318.

(c) The first digital data are read from the line buffer 318 and then transmitted to both a memory 321 and an outer-code parity (PO) decoding module 320 to perform outer-code parity decoding and correction. The PO decoding module 320 comprises a PO decoder 323, which is in charge of outer-code parity decoding on the first digital data. The operation of outer-code parity decoding is to vertically decode data of an ECC block; however the data read from the line buffer 318 are lateral parts of an ECC block. As a result, the PO decoder 323 performs a current outer-code parity decoding according to both data read from the line buffer 318 and a temporary result stored in a line buffer 324. The temporary result is generated by the PO decoder 323 by performing an outer-code parity decoding on the former received data. The result of the current outer-code parity decoding is then stored in the line buffer 324 as well. Here is an example to illustrate the above procedure. When vertically decoding the first column of an ECC block, the PO decoder 323 performs outer-code parity decoding on the first byte of the first row data of an ECC block, and the result generated by the PO decoder 323 is temporarily stored in the line buffer 324. The PO decoder 323 proceeds to perform outer-code parity decoding on the first byte of the second row data of the ECC block. The PO decoder 323 reads the previous decoding result from the line buffer 324 and then performs outer-code parity decoding on the current data by referring to the previous decoding result. The new decoding result is also stored in the line buffer 324 as a reference for future any decoding process. Consequently, the PO decoder 323 and the line buffer 324 complete the outer-code decoding process by following the feedback procedure. The data stored in the line buffer 324 are transmitted to the memory 321 and the PO correction unit 325. Afterwards, the PO correction unit 325 generates a correction data according to the data outputted by the line buffer 324. The memory 321 then receives the correction data, according to which the data stored in the memory 321 are corrected by PO correction.

(d) The above mentioned procedure is repeated until the first digital data transmitted to the memory 321 by the line buffer 318 and the data that are already PO decoded and transmitted to the memory 321 from the line buffer 324 form a complete ECC block. The PO correction unit 325 corrects the data stored in the memory 321 according to the correction data, and then the EDC detection unit plus the host interface 319 check every error detection code of every sector in an ECC block stored in the memory 321. If every error detection code of every sector is correct, then the ECC block in the memory 321 is transmitted to the host 322 via the EDC detection unit plus the host interface 319.

In summary, compared to the DVD data accessing system 200 disclosed in the U.S. Pat. No. 6,662,335, the DVD data accessing system 300 requires less memory bandwidth and hence the system efficiency is improved.

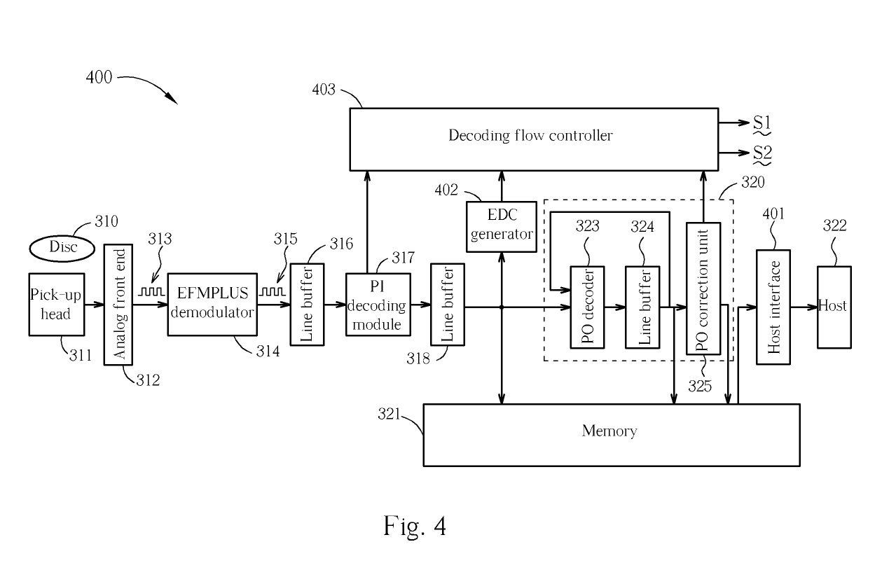

Please refer to FIG. 4. FIG. 4 shows a DVD data accessing system 400 according to a second embodiment of the present invention. The structure of the DVD data accessing system 400 is similar to that of the DVD data accessing system 300, except that in the DVD data accessing system 400, the host interface 401 is now merely in charge of transmitting data, and the EDC check function is now being executed by an additional EDC generator 402. Furthermore, the DVD data accessing system 400 further comprises a decoding flow controller 403 for controlling the decoding procedure. The EDC generator 402 is coupled to the line buffer 318, so the line buffer 318 sends the first digital data to not only the PO decoding module 320 and the memory 321 but also to the EDC generator 402. Whenever the data received by the EDC generator 402 can be assembled as a sector, the EDC generator 402 generates the corresponding EDC of the sector, and then checks if the data of the entire sector are correct. Finally, the result of the check step is sent to the decoding flow controller 403.

Besides being coupled to the EDC generator 402, the decoding flow controller 403 is also coupled to the PI decoding module 317 and the PO correction unit 325. The PI decoding module 317 generates a PI error condition code according to the decoding result; similarly, the PO correction unit 325 generates a PO error condition code according to the decoding result. The decoding flow controller 403 receives the PI error condition code and the PO error condition code and then outputs a signal SI to determine if the decoding and correction of PI or PO are needed to be performed again on one sector. The decoding flow controller 403 also determines if the data of one sector are correct and outputs a signal S2 to indicate that data are required to be read again from the disc 310 according to a predetermined condition, e.g., the PI error condition code indicating correct decoding, the PO error condition code indicating correct decoding, and the EDC indicating incorrect decoding. As a result, before the data are transmitted to the host interface 401, the data are checked and ensured correct.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An apparatus for accessing data on an optical disc, comprising:
an inner-code parity (PI) decoding module, for PI decoding and correcting a piece of digital data read from the optical disc to generate a piece of first digital data;
a storage device for storing the first digital data outputted from the PI decoding module; and
an outer-code parity (PO) decoding module, for PO decoding and correcting the first digital data outputted from the PI decoding module to generate a piece of second digital data, and writing the second digital data to the storage device;
wherein the first digital data are a portion of an error correction code (ECC) block.

2. The apparatus for accessing data on an optical disc of claim 1 further comprising:
an error detection code (EDC) generator for generating at least an EDC according to the first digital data outputted from the storage device.

3. The apparatus for accessing data on an optical disc of claim 1 further comprising:
an error detection code (EDC) generator for generating at least an EDC according to the first digital data outputted from the PI decoding module;
a decoding flow controller for generating a control signal according to at least one of the following data: a first error condition code generated by the PI decoding module, a second error condition code generated by the PO decoding module, and the EDC.

4. The apparatus for accessing data on an optical disc of claim 3, wherein when the first and the second error condition codes and the EDC correspond respectively to a predetermined condition, the decoding flow controller outputs the control signal.

5. The apparatus for accessing data on an optical disc of claim 3, wherein the control signal causes the PI decoding module and the PO decoding module to execute the decoding and correcting procedures again.

6. The apparatus for accessing data on an optical disc of claim 3, wherein the control signal causes the data accessing apparatus to read the data from the optical disc again.

7. The apparatus for accessing data on an optical disc of claim 1, wherein the PO decoding module comprises:
a decoding unit for performing PO decoding;
a third line buffer for storing the decoding result of the decoding unit and writing the decoding result to the storage device; and
a correcting unit, coupled to the third line buffer and the storage device, for generating a piece of correction data according to the data stored in the third line buffer, the correction data being utilized to correct the data stored in the storage device;
wherein the decoding unit performs PO decoding according to the first digital data outputted from the PI decoding module and the decoding result of the decoding unit outputted from the third line buffer.

8. The apparatus for accessing data on an optical disc of claim 1, wherein the optical disc is a digital versatile disc (DVD).

9. The apparatus for accessing data on an optical disc of claim 1, wherein the PI decoding module comprises a second line buffer for storing the first digital data and outputting the first digital data to the storage device and the PO decoding module.

10. The apparatus for accessing data on an optical disc of claim 1 further comprising:
a first line buffer for storing the digital data read from the optical disc and outputting the digital data to the PI decoding module.

11. A method for accessing data on an optical disc comprising:
reading data from the optical disc to generate a piece of digital data;
generating a piece of first digital data by PI decoding and correcting the digital data;
storing the first digital data in a second line buffer and a storage device; and
generating a piece of second digital data by PO decoding and correcting the first digital data outputted from the second line buffer and storing the second digital data in the storage device;
wherein the first digital data are a portion of an error correction code (ECC) block.

12. The method of claim 11 further comprising:
generating at least an EDC according to the first digital data stored in the storage device.

13. The method of claim 11 further comprising:
generating at least an EDC according to the first digital data stored in the second line buffer;
generating a first error condition code by PI decoding and correcting the digital data generating by reading data from the optical disc;
generating a second error condition code by PO decoding and correcting the first digital data outputted from the second line buffer; and
generating a control signal according to the first error condition code, the second error condition code, and the EDC.

14. The method of claim 13, wherein when the first and the second error condition codes and the EDC correspond respectively to a predetermined condition, the control signal is generated.

15. The method of claim 13, wherein the control signal indicates repeats of the PI decoding and correcting procedure and the PO decoding and correcting procedure.

16. The method of claim 13, wherein the control signal indicates a reread of the data on the optical disc.

17. The method of claim 11, wherein the step of generating the second digital data comprises:
PO decoding the first digital data;
storing the decoding result of the PO decoding process in a third line buffer; and
writing the data stored in the third line buffer to the storage device, and generating a piece of correction data according to the data stored in the third line buffer, the correction data being utilized to correct the data stored in the storage device.

18. The method of claim 11, wherein the optical disc is a digital versatile disc (DVD).

19. The method of claim 11, wherein the step of reading data from the optical disc to generate a piece of digital data further comprises:
storing the digital data in a first line buffer.

20. A method for accessing data on an optical disc comprising:
(a) reading data from the optical disc to generate a piece of digital data, wherein the digital data correspond to an error correction code (ECC) block;
(b) PI decoding and correcting a portion of the digital data;
(c) PO decoding and correcting the result generated in step (b) and storing the result of the PO decoding and correcting process in a storage device; and
(d) repeating steps (b) and (c) until the entire digital data are PI and PO decoded and corrected.
